(19) United States
(12) Patent Application Publication
(10) Pub. No.: US 2002/0089338 A1
(43) Pub. Date: Jul. 11, 2002

(54) Brake oil detector

(76) Inventor: Tien-Tsai Tseng, Taichung Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/756,207

(22) Filed: Jan. 9, 2001

(51) Int. Cl. G01R 27/08

(52) U.S. Cl. 324/698

(57) ABSTRACT

A brake oil detector including a housing in which a pipe member, a detecting unit and an alerting unit are disposed. Two ends of the pipe member are respectively connected with two connectors for communicating with an oil draining pipeline for making the brake oil flow through the pipe member during renewal of the brake oil. The detecting unit has a set of electrodes extending into the pipe member. When renewing the brake oil, the set of electrodes serve to detect whether the old deteriorated brake oil has been completely exhausted from the brake pipeline and renewed.

### BACKGROUND OF THE INVENTION

The present invention is related to a brake oil detector which is able to synchronously detect the quality of the flowing brake oil during renewal of the brake oil.

FIG. 6 shows a conventional brake oil detector. A detecting circuit (not shown) is disposed in a housing 81 and connected with a cable 82 extending out of the housing 81. The end of the cable 82 has a set of electrodes 83. Indicator lamps 84 are arranged on the housing 81.

In use, the brake oil will be boiled at high temperature to generate water. After the brake oil contains water to a certain ratio, the brake oil will be deteriorated and the pressure will be transmitted from the brake oil to the brake pump at lower efficiency.

When using the brake oil detector, the electrodes 83 are immerged into the brake oil in the brake master cylinder 85. After the amount of the water contained in the brake oil increases, the capacity will increase, while the impedance will decrease. Therefore, by means of the electrodes 83, the amount of the water contained in the brake oil can be measured for judging whether the brake oil is deteriorated.

When replacing the brake oil, an oil draining pipe is connected with the brake wheel cylinder and new brake oil is added into the brake master cylinder, whereby the old deteriorated brake oil is drained out from the draining pipe of the brake wheel cylinder. The old deteriorated brake oil will have darker and foul color. Accordingly, a worker can judge from the color of drained brake oil whether the old deteriorated brake oil has been totally drained. When replacing the old brake oil, the new brake oil is added into the brake master cylinder. Therefore, it is impossible to use the above brake oil detector to detect whether the old deteriorated brake oil has been renewed.

The above judgement is visually made by the worker so that there is often an error. Moreover, when the new brake oil is added, the new brake oil will be mixed with the old brake oil so that the new brake oil will contain some water. That is, even if the brake oil no more has darker foul color, it may still contain water. With the conventional visual inspection, such difference can be hardly noticed. As a result, the new brake oil may still contain water therein and the deterioration of the brake oil will be speeded.

### SUMMARY OF THE INVENTION

It is therefore a primary object of the present invention to provide a brake oil detector in which the pipe member in the housing is communicated with the oil draining tube for renewing the brake oil. Therefore, the drained brake oil will flow through the pipe member. A first set of electrodes of the detecting unit are extended into the pipe member. During the entire dynamic renewal procedure of the brake oil, the first set of electrodes can synchronously detect whether the old deteriorated brake oil has been totally drained and renewed. Therefore, the detection can be made in dynamic state.

It is a further object of the present invention to provide the above brake oil detector in which a second set of electrodes is connected with the detecting unit via an extension wire. The second set of electrodes can be pulled out of the housing and extended into the brake master cylinder for detecting the brake oil in static state.

The present invention can be best understood through the following description and accompanying drawings wherein:

### BRIEF DESCRIPTION OF THE DRAWINGS

FIG. 1 is a top view of the brake oil detector of the present invention;

FIG. 2 is a perspective exploded view of the brake oil detector of the present invention;

FIG. 3 is a partially sectional view of the brake oil detector of the present invention;

FIG. 4 shows that the brake oil detector of the present invention is used to detect the brake oil in static state;

FIG. 5 shows that the brake oil detector of the present invention is used to detect the brake oil in dynamic state; and

FIG. 6 shows the use of a conventional brake oil detector.

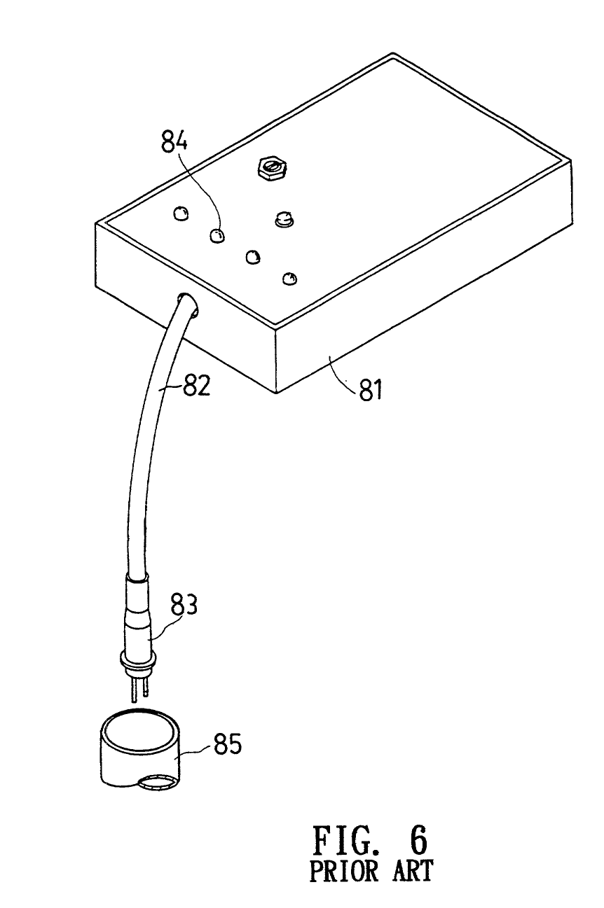

### DETAILED DESCRIPTION OF THE PREFERRED EMBODIMENTS

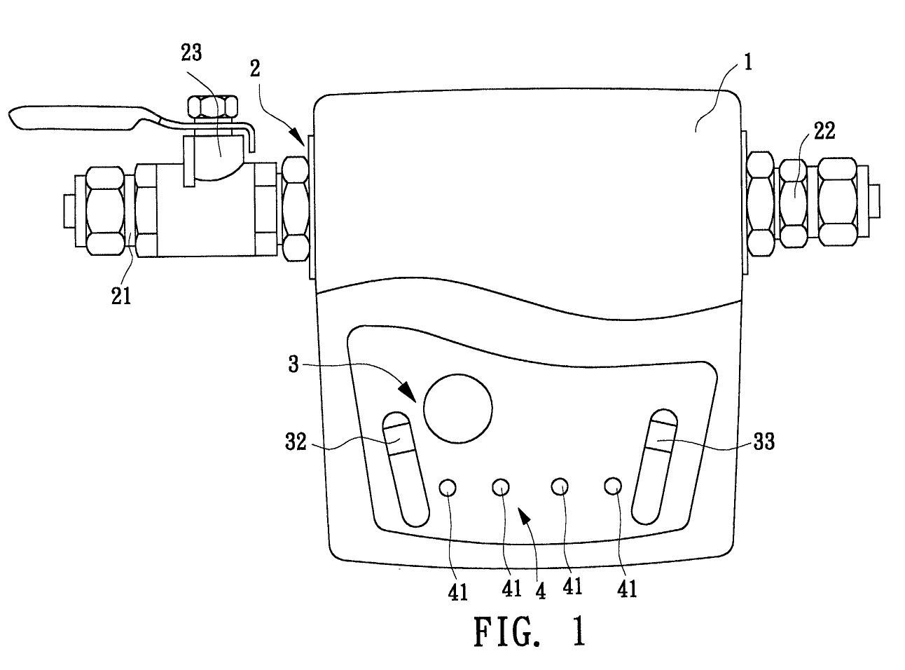

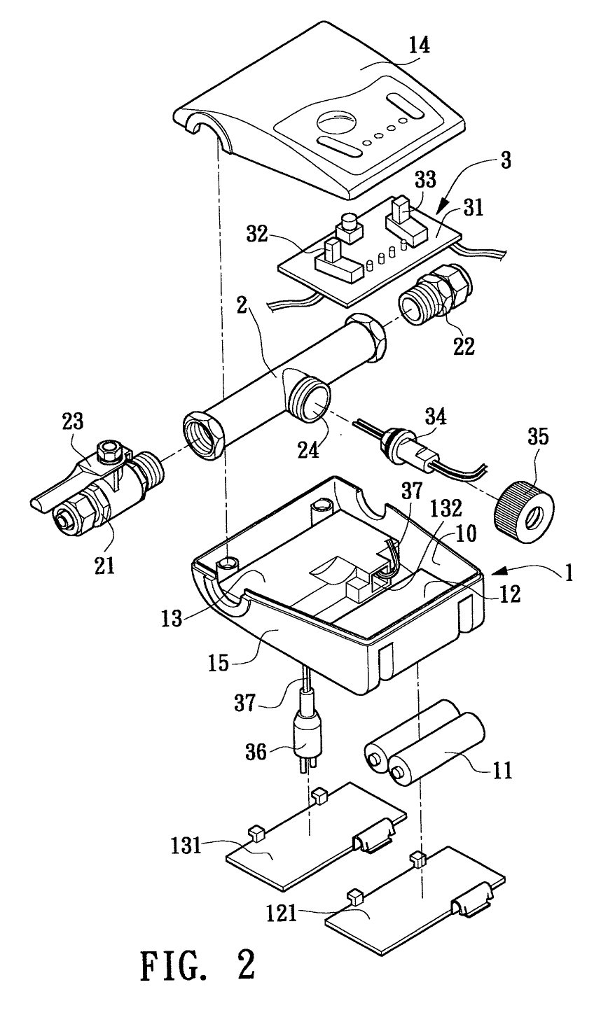

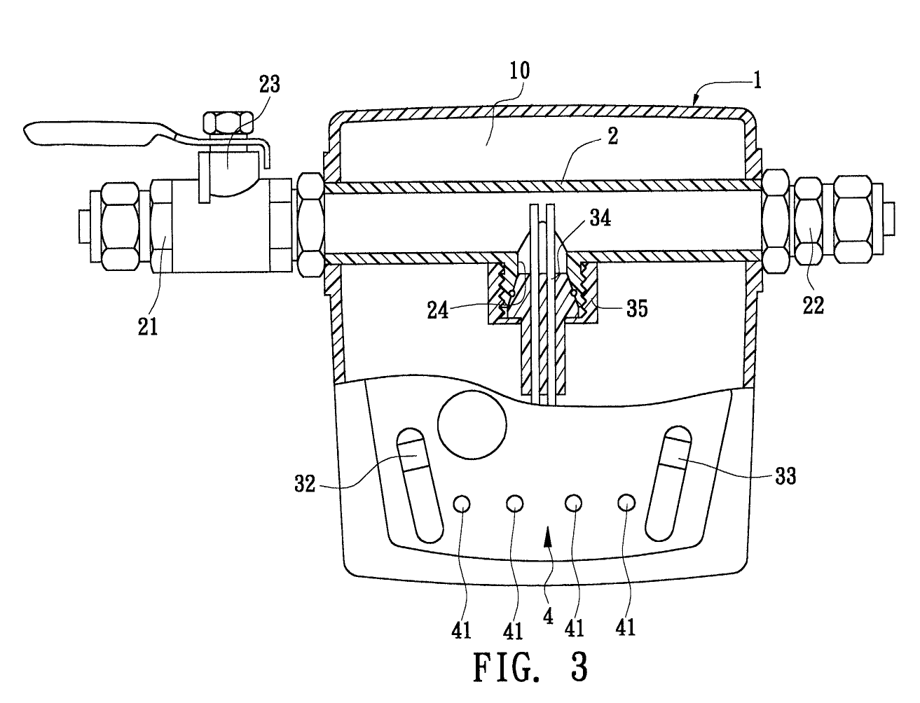

Please refer to FIGS. 1 to 3. The brake oil detector of the present invention includes a housing 1 composed of an upper casing 14 and a lower casing 15 defining a receiving space 10 in the housing 1. A pipe member 2, a detecting unit 3 and an alerting unit 4 are disposed in the receiving space 10. The lower casing 15 is formed with a first receptacle 12 for placing cells 11 therein. The first receptacle 12 is covered by a cover 121.

Two ends of the pipe member 2 are respectively coupled with two connectors 21, 22 for communicating with a pipeline of brake oil, whereby the brake oil can flow through the pipe member 2. A pipeline switch 23 is disposed on the connector 21 for controlling the passage of the pipe member 2. A middle section of the pipe member 2 has a bypass 24.

The detecting unit 3 has a circuit board 31 disposed in the housing 1. A power switch 32 and a sorting switch 33 are arranged on the circuit board 31 and protrude out of the housing I for controlling turning on/off of the detecting unit 3. The circuit board 31 has a first set of electrodes 34 extending from the bypass 24 into the pipe member 2. The first set of electrodes 34 are fixed in the bypass 24 by a cap 35. The sorting switch 33 is switched according to the classifications of different brake oils. The detecting unit 3 further includes a second set of electrodes 36 connected with the circuit board 31 via an extension wire 37. The lower casing 15 further has a second receptacle 13 for receiving therein the second set of electrodes 36 and the extension wire 37. The second receptacle 13 has an opening 132 communicating with the interior of the housing 1. The extension wire 37 is passed through the opening 132 to connect with the circuit board 31. The second receptacle 13 is covered by an openable cover 131, whereby the second set of electrodes 36 can be pulled out of the housing 1 and extended into the brake master cylinder. The detecting unit 3 is connected with the alerting unit 4.

The alerting unit 4 includes a group of signal lamps 41 for indicating the detected state of the brake oil.

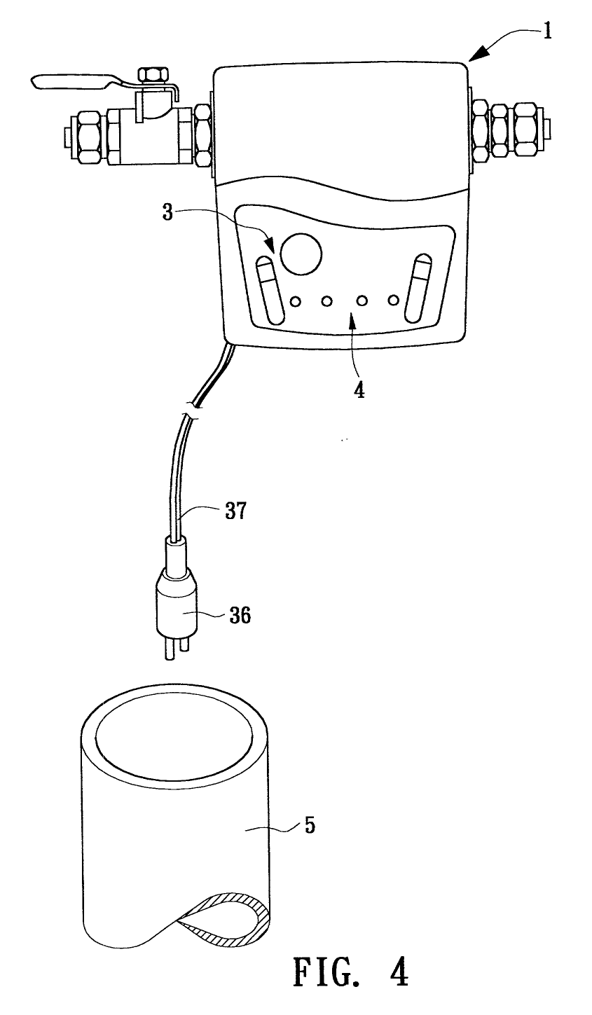

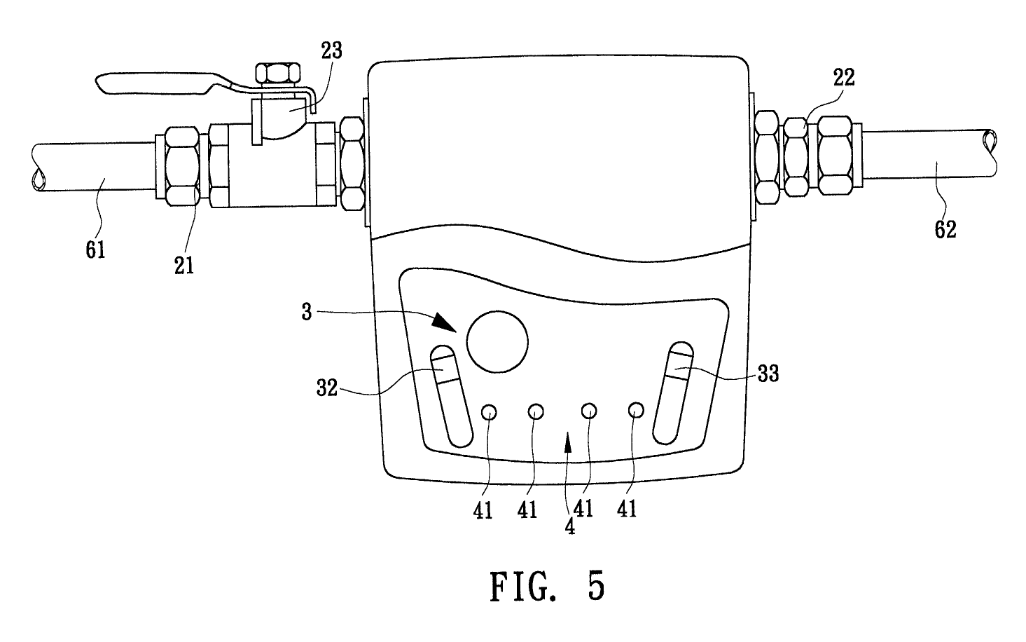

In static detection, as shown in FIG. 4, the cover 131 is opened and the extension wire 37 and the second set of electrodes 36 are pulled out. The second set of electrodes 36 are extended into the brake master cylinder 5 to measure the water content of the brake oil. When renewing the brake oil, an oil draining tube 61 is connected between the brake wheel cylinder and the connector 21 of the pipe member 2. The pipeline switch 23 is switched on and the other connector 22 is connected with an oil exhaust tube 62. At this time, the pipe member 2 is in a free state as shown in FIG. 5. The new brake oil is added into the brake master cylinder to make the old deteriorated brake oil flow from the oil draining tube 61 of the brake wheel cylinder through the pipe member 2 and discharge from the oil exhaust tube 62. During renewal of the brake oil, the first set of electrodes 34 of the detecting unit 3 are extended into the pipe member 2. Therefore, during the entire dynamic renewal procedure of the brake oil, the first set of electrodes 34 can synchronously detect the quality of the brake oil after renewed. In the case that the signal lamps 41 of the alerting unit 4 indicate that the brake oil in the pipe member 2 has good quality, it means that the old deteriorated brake oil has been entirely exhausted from the pipeline of the brake system and renewed. At this time, the pipeline switch 23 is switched off to stop the brake oil from being further discharged. Then the oil draining tube 61 connected with the brake wheel cylinder is closed. Accordingly, it is ensured that the brake oil has good quality after renewed.

In conclusion, the pipe member 2 in the housing 1 is communicated with the oil draining tube 61 for renewing the brake oil. Therefore, the drained brake oil will flow through the pipe member 2. During the entire dynamic renewal procedure of the brake oil, the first set of electrodes 34 of the detecting unit 3 are extended into the pipe member 2. Therefore, the first set of electrodes 34 can synchronously detect whether the old deteriorated brake oil has been totally drained and renewed. Therefore, the detection can be made in dynamic state. Furthermore, the second set of electrodes 36 can be pulled out of the housing 1 and extended into the brake master cylinder 5 for detecting the brake oil in static state. Accordingly, the present invention serves to detect the brake oil in both dynamic and static states.

The above embodiments are only used to illustrate the present invention, not intended to limit the scope thereof. Many modifications of the above embodiments can be made without departing from the spirit of the present invention.

What is claimed is:

1. A brake oil detector comprising a housing in which a pipe member, a detecting unit and an alerting unit are disposed, wherein:
two ends of the pipe member are respectively connected with two connectors for communicating with a pipeline of the brake oil, whereby the brake oil can flow through the pipe member;
the detecting unit has a switch for controlling turning on/off of the detecting unit, the detecting unit further having a set of electrodes extending into the pipe member, the detecting unit being connected with the alerting unit; and
the alerting unit includes at least one electric element for emitting an alerting signal.

2. A brake oil detector as claimed in claim 1, wherein the housing is composed of an upper casing and a lower casing defining a receiving space in the housing for receiving the pipe member, detecting unit and alerting unit, the lower casing being formed with a first receptacle for placing cells therein, the first receptacle being covered by a cover.

3. A brake oil detector as claimed in claim 1, wherein the detecting unit further includes a sorting switch which is switched according to the classifications of different brake oils.

4. A brake oil detector as claimed in claim 1, wherein the detecting unit further includes a second set of electrodes connected with the detecting unit via an extension wire, the housing further having a second receptacle for receiving therein the second set of electrodes and the extension wire, the second receptacle having an opening communicating with the interior of the housing, the extension wire being passed through the opening to connect with the detecting unit, the second receptacle being covered by an openable cover, whereby the second set of electrodes can be pulled out of the housing for use.

5. A brake oil detector as claimed in claim 1, further comprising a pipeline switch disposed on the pipe member for controlling opening/closing of the pipe member.

6. A brake oil detector as claimed in claim 1, wherein the electric element of the alerting unit is a signal lamp for emitting alerting signal.
